(19) United States
(12) Patent Application Publication
(10) Pub. No.: US 2025/0258445 A1
(43) Pub. Date: Aug. 14, 2025

(54) FIDUCIAL PATTERN ALIGNMENT TECHNIQUES

(71) Applicant: Onto Innovation Inc., Wilmington, MA (US)

(72) Inventors: John M. Thornell, McKinney, TX (US); Longjiang Xiang, Tianjin (CN); Xin Song, Andover, MA (US); Keith F. Best, Andover, MA (US)

(21) Appl. No.: 19/042,393

(22) Filed: Jan. 31, 2025

(30) Foreign Application Priority Data
Feb. 14, 2024 (WO) PCT/CN2024/077197

(51) Int. Cl. G03F 9/00

(52) U.S. Cl. CPC G03F 9/7049; G03F 9/7076; G03F 9/708; G03F 9/7092

(57) ABSTRACT

A photolithography machine with an alignment system is described. The photolithography machine can identify a fiducial pattern provided on a substrate and use the location of the fiducial pattern to align the substrate before exposure. The fiducial pattern can include a plurality of fiducial markings arranged in a specified pattern. A model matching technique can be applied to match the respective individual fiducial markings. A shaping technique can then be used to identify the fiducial pattern based on the matched fiducial markings.

### CROSS-REFERENCE TO RELATED APPLICATION

This application claims the benefit of International Application No. PCT/CN2024/077197, filed Feb. 14, 2024, which application is hereby incorporated by reference herein in its entirety.

### TECHNICAL FIELD

The present disclosure generally relates to alignment techniques associated with photolithographic processing, in particular techniques to align fiducials including specified patterns.

### BACKGROUND

Photolithography is typically used to fabricate patterns on a substrate, such as a silicon (semiconductor) wafer or a flat panel display. Generally, photolithography involves transferring a pattern from a photomask (or reticle) to a photosensitive surface on a substrate.

A robot is used to place the substrates onto a substrate stage within the photolithographic machine to prepare the substrate for processing. Typically, the substrate has one or more fiducial indicators (e.g., a notch, flat portion, pattern on the edge of the substrate) etched or otherwise formed into the edge of the substrate. Alignment processes are used to align the substrate using the fiducial indicators.

### SUMMARY

Techniques for determining a true center position of a fiducial marking, such as a laser-drilled hole, are described. A template of the fiducial marking can be used to match the fiducial marking in a captured image of a substrate. A rough center position of the fiducial marking can be determined based on the template matching. Next, a true center position of the fiducial marking can be determined that maximizes the sum or mean of gradient magnitude within the shape of the fiducial marking.

A photolithography machine with an alignment system is described herein. The photolithography machine can identify a fiducial pattern provided on a substrate and use the location of the fiducial pattern to align the substrate before exposure. The fiducial pattern can include a plurality of fiducial markings arranged in a specified pattern. While some conventional techniques attempt to identify the fiducial pattern as a whole instantly, the techniques described herein first apply model matching technique to match the respective individual fiducial markings. A shaping technique can then be used to identify the fiducial pattern based on the matched fiducial markings.

### BRIEF DESCRIPTION OF THE DRAWINGS

Various ones of the appended drawings merely illustrate example embodiments of the present disclosure and should not be considered as limiting its scope.

FIG. 1A illustrates example portions of a photolithography machine.

FIG. 1B illustrates example portions of a projection system.

FIG. 2 shows a simplified block diagram of components of a microscope camera.

FIG. 3 is a flow diagram for a method for aligning a laser-drilled hole.

FIG. 4 illustrates an example of where the best fit circle yields the maximum gradient inside the circle.

FIG. 5 illustrates is a flow diagram for a method for refining center position of a hole based on gradient magnitude values.

FIG. 6 shows some example cases of determining an actual center of a laser-drilled hole using the techniques described herein as compared to traditional template matching.

FIG. 7 illustrates an example of a fiducial pattern.

FIG. 8 illustrates a flow diagram for a method for fiducial alignment.

FIG. 9 illustrates an example of a median circle fit technique.

FIG. 10 illustrates an example of a median circle fit technique being applied to a fiducial pattern.

FIG. 11 is a flow diagram for a method for generating fiducial variance information.

FIG. 12 illustrates a block diagram of an example machine upon which any one or more of the techniques (e.g., methodologies) discussed herein may be performed.

### DETAILED DESCRIPTION

A substrate can include fiducials for alignment purposes. In some examples, the fiducials can be provided as fiducial patterns comprised of individual fiducial markings, e.g., circular pattern of laser drilled holes. A photolithography machine with an alignment system can identify the fiducial pattern and use the location of the fiducial pattern to align the substrate before exposure. However, manufacturing variations can cause imperfections in the fiducial markings, making identifying the fiducial pattern difficult.

Alignment techniques described herein can be used to improve identifying and locating the fiducial pattern. For individual fiducial markings, such as laser-drilled holes, a true center position can be determined that that maximizes the sum or mean of gradient magnitude within the shape of the fiducial marking.

For fiducial patterns with a plurality of fiducial markings, a model matching technique can be used to match the respective individual fiducial markings first instead of attempting to identify the fiducial pattern as a whole instantly. Next, a shaping technique can be used to identify the fiducial pattern based on the matched fiducial markings. Outlier values may be removed by the shaping technique to make the fiducial pattern identification more robust and resistant to manufacturing variations.

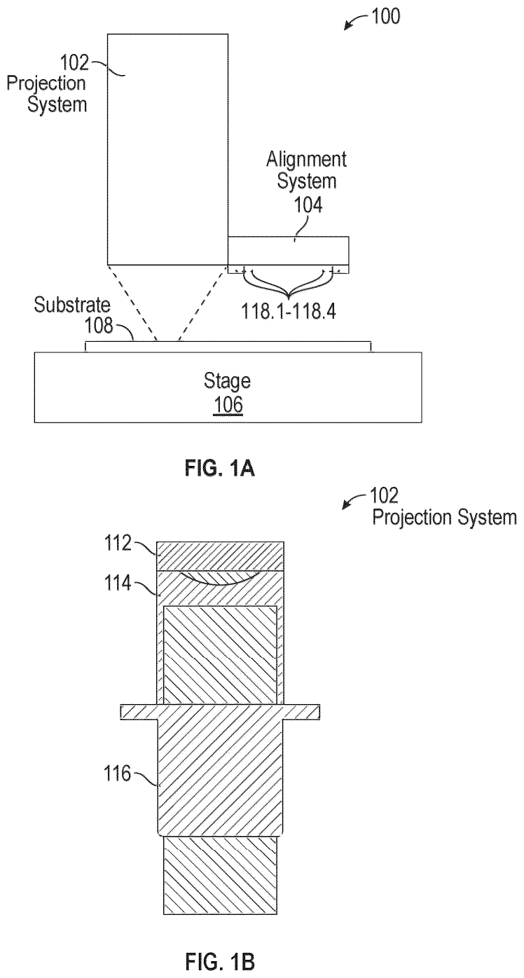

FIGS. 1A and 1B illustrate example portions of a photolithography machine 100. The photolithography machine 100 may include a projection system 102, an alignment system 104, and a stage for carrying one or more substrates 108. The projection system 102 and alignment system 104 may be positioned adjacent to each other and may be positioned opposite (e.g., above) the stage 106.

The projection system 102 may include one or more projection camera systems. FIG. 1B illustrates example portions of a projection system 102. The projection system 102 may include an illuminator 112, a reticle stage 114, and a projection lens 116. The projection system 102 may be configured to expose patterns or images onto the substrate in respective exposure regions. One or more projection camera systems may be provided. If a plurality of projection camera systems are provided, then the projection camera systems may be configured to expose their respective patterns or images substantially at the same time (e.g., concurrently or simultaneously).

The illuminator 112 may include a light source to generate light on top of the reticles placed on the reticle stage 114, respectively. The light source may be provided using a UV LED (ultra-violet light emitting diode) system and associated optics.

The reticle stage 114 may include alignment devices to align the reticle placed thereon relative to the stage 106. The alignment devices may include a 6-axis reticle chuck, as described for example in U.S. Pat. No. 7,285,971, entitled “High Speed Lithography Machine and Method,” which is incorporated herein by reference in its entirety, including but not limited to those portions that specifically appear hereinafter, the incorporation by reference being made with the following exception: In the event that any portion of the above-referenced patent is inconsistent with this application, this application supersedes the above-referenced patent. Each axis of the 6-axis chuck may have built-in single-axis, coarse, velocity and position sensors.

In the examples of multiple camera systems, each reticle stage may be configured to hold a separate reticle (or photomask or image source) to allow for different pattern fabrication. The reticle stages may be aligned independently relative to the stage to account for different variations on the substrate or different pattern fabrication. Each camera system may have its own set of sensors to align its photomask (or reticle) with the substrate plane to ensure that an optical axis of the camera is perpendicular to the substrate plane. For example, the sensors (e.g., six sensors) for each camera may use a metrology frame as reference for proper alignment. The metrology frame may be straight and rigid and therefore provide a reference for flatness, straightness, height, position, etc.

The reticle stage 114 may be aligned independently relative to the stage to account for different variations on the substrate or different pattern fabrication. The projection lens 116 may project the pattern or image on each of the reticles onto the substrate placed on the stage. The projection lens 116 may include one or more optical lenses. The projection lens 116 may include individual, real-time, auto focus sensors. The optical properties of the projection lens 116 may be adjusted based on the auto-focus sensors to focus the projected pattern or image on the substrate as needed.

The stage 106 may be provided below the cameras and may carry one or more substrates during fabrication. The stage may include a granite structure. The stage may be movable in the x, y, and θ directions.

The alignment system 104 may be used to align the substrate, and in particular respective exposure regions of the substrate before exposure by the projection camera system. The alignment system may include one or more microscope cameras 118.1-118.4. For example, alignment system may include four microscope cameras 118.1-118.4. The alignment system 104 may include a supporting structure supporting the plurality of microscope cameras 118.1-118.4.

The microscope cameras 118.1-118.4, as described herein, can image and detect fiducials at various positions on the substrate. Moreover, the microscope cameras 118.1-118.4 may be used to detect fiducials not just on the top surface of the substrate, but on the bottom surface or intermediate layers (with the use of infrared sensors).

The microscope cameras 118.1-118.4 may be top mounted on the supporting structure. In some examples, the microscope cameras 118.1-118.4 may be arranged in a rectangular formation, with each camera located at a corner of the rectangular formation. The microscope cameras 118.1-118.4 may be movable in the x,y direction to accommodate different fiducial positions for various substrate recipes. An x,y actuator may be provided with a gripper arm to grab each microscope and position each microscope cameras 118.1-118.4. In some examples, one microscope camera 118.1 may be kept stationary, and the other microscope cameras 118.2-118.4 may be moved relative to the stationary microscope camera 118.1.

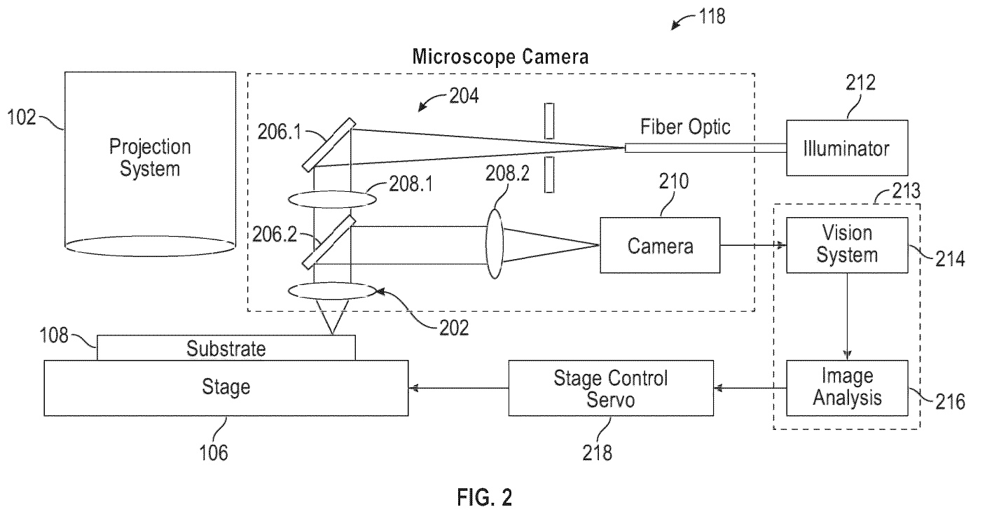

FIG. 2 shows a simplified block diagram of components of a microscope camera 118. The microscope camera 118 may include microscope objective 202, an optical system 204 with fold mirrors 206.1-206.2 and lenses 208.1-208.2, a camera 210, and an illuminator 212. The illuminator 212 may provide bright field and/or dark field LED illumination. The camera 210 may be provided as an image sensor, such as a CMOS or CCD sensor. In some examples, the camera 210 may be provided as an infrared sensor, such as InGaAs sensor.

The camera 210 may be coupled to a processor 213 including a vision system module 214 and an image analysis module 216. The processor 213 may process the images generated by the camera and analyze the images to detect and determine the location of the fiducial using the techniques described in further detail below. Based on the locations of other fiducials associated with the plurality of cameras, alignment correction information may be calculated. Based on the alignment correction, the stage 106 may be moved to adjust the position of the substrate by a stage control servo 218 prior to exposure of the respective exposure region.

The alignment correction information may also be used by the projection system 102 to adjust its components, as described, above before exposure of the respective exposure region. The alignment correction information may be used to adjust x, y offset, θ, magnification, etc.

In some examples, a fiducial can be provided as a laser-drilled hole/via. Laser drilling possesses advantages such as high precision, non-contact processing, and minimal thermal impact, making it suitable for applications requiring small hole diameters and intricate structures. Laser drilling's efficiency, applicability to various materials, and flexibility contribute to widespread use in industrial manufacturing. Identifying and locating drilled holes can be difficult because of issues, such as manufacturing variations, noise in images, etc., which can affect accurate positioning of the drilled holes.

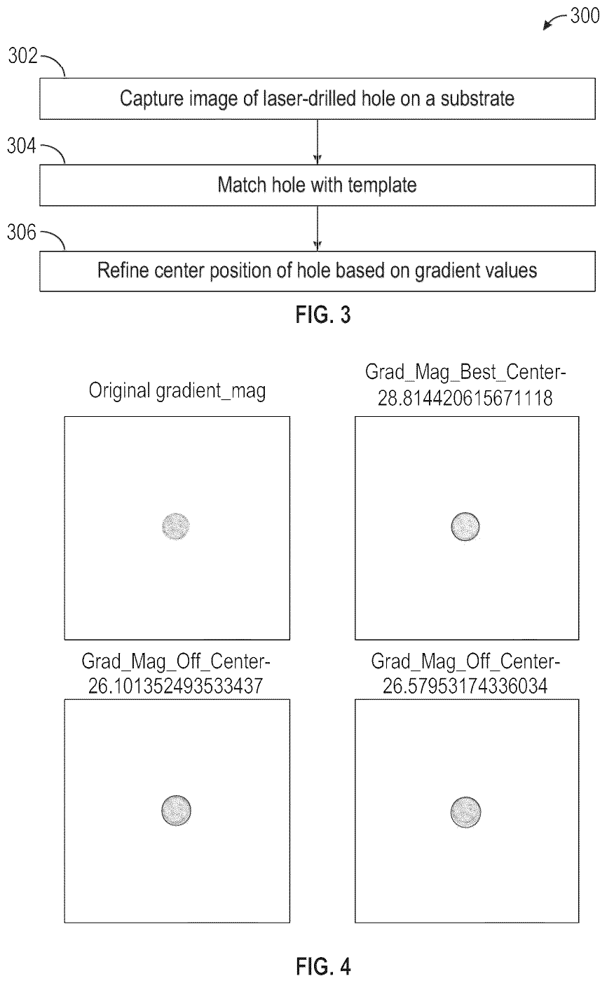

Next, improved alignment techniques for laser-drilled holes and other shapes are described. FIG. 3 is a flow diagram for a method 300 for aligning a fiducial marking, such as a laser-drilled hole. At operation 302, a microscope camera captures an image of a laser-drilled hole on a substrate. In some examples, the hole may be provided as a fiducial marking at the corner or some other specified location of an exposure region of the substrate.

At operation 304, the hole in the image is matched with a template of the hole. The template can be an image of a model hole. In some examples, normalized cross correlation technique may measure the cross-correlation between pixel values in the captured image and the template at respective displacements while normalizing the correlation by a standard deviation of the two inputs. That is, the template can be slid over the captured image, and the normalized cross-correlation at each position can be calculated. The calculations can identify positions with high correlation scores to locate instances of the hole in the image.

The template matching can find a rough position of the hole, but for some cases, the found center of hole can be shifted from the real (true) hole center. At operation 306, the center position of the hole is refined based on maximizing the sum or mean of gradient magnitude within the shape of the hole.

If the detected center deviates from the actual center of the hole, some edge pixels will fall outside the shape of the hole. This is because edge pixels typically exhibit a strong gradient magnitude signal, whereas pixels inside the hole have a relatively lower probability of having a strong gradient magnitude. Consequently, when the center of the hole aligns with its true center, it should yield the highest value for the sum or mean of the gradient magnitude.

The objective of operation 306 can be expressed as the following equation:

maxmize gradₘₑₐₙ(x,y)

Here, gradₘₑₐₙ(x, y) means when the center is at (x, y), the mean of gradient magnitude inside the hole.

FIG. 4 illustrates an example of where the best fit circle yields the maximum gradient inside the circle. Note that the circles offset from the center exhibit lower gradients.

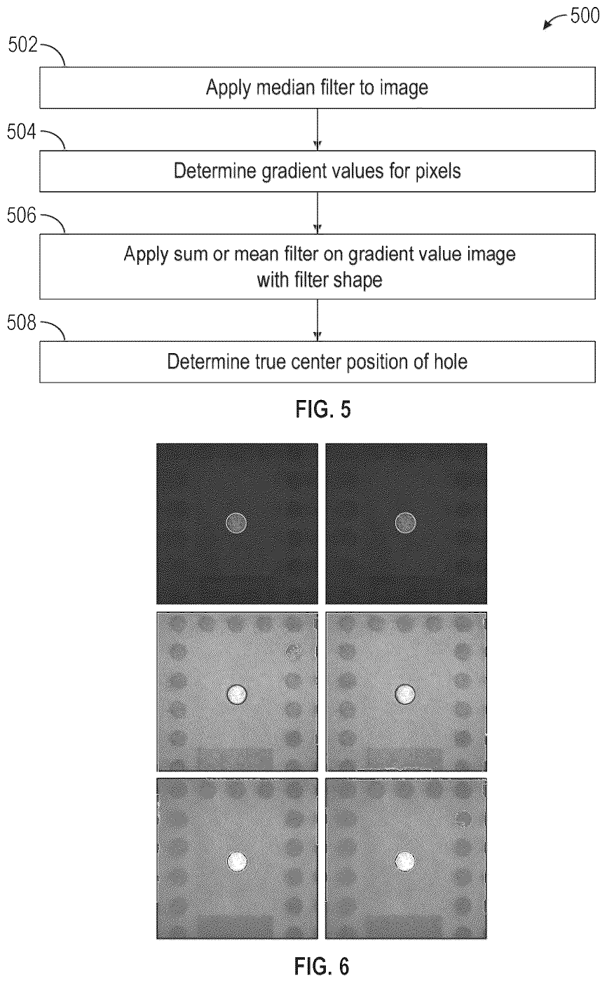

FIG. 5 illustrates is a flow diagram for a method 500 for refining center position of a hole based on gradient magnitude values. Method 500 can be applied to an image of a substrate including a hole. The hole in the image can be matched to a template to determine a rough position of the hole, as described above.

At operation 502, a median filter is applied to the image of the hole. The median filter can reduce noise while preserving edges and details in an image. The median filter can replace the intensity value of each pixel with the median value of neighboring pixels.

At operation 504, gradient values for a set of pixels in the image (or a portion containing the rough position of the hole) are determined. For example, a Sobel filter can be applied to determine the gradient values. The Sobel filter can include horizontal (x direction) and vertical (y direction) operators to be applied to the image for detecting changes in intensity in the horizontal and vertical directions, respectively. The Sobel operators can be defined as:

$${G}_{x} = [ \begin{matrix}- 1 & 0 & 1 \\ - 2 & 0 & 2 \\ - 1 & 0 & 1\end{matrix} ]$$

$${G}_{y} = [ \begin{matrix}- 1 & - 2 & - 1 \\ 0 & 0 & 0 \\ 1 & 2 & 1\end{matrix} ]$$

The gradient magnitude at each pixel can be calculated by:

$$G = \sqrt{( {G}_{x}^{2} + {G}_{y}^{2} )}$$

At operation 506, a sum (or mean) filter is applied on the gradient value image with filter shape, such as a nominal circle. The nominal circle may be obtained based on the template of the hole. For example, the nominal circle may have the same dimensions (e.g., radius) as the hole template. That is, the nominal circle can be slid over the gradient value of the image, and the value of filter at each position can be calculated.

At operation 508, the surface correlation results may be analyzed and a true center of position of the hole may be determined. The determined center of the hole corresponds to the highest value for the sum or mean of the gradient values.

FIG. 6 shows some example cases of determining an actual center of a laser-drilled hole using the techniques described herein (e.g., methods 300 and 500) as compared to traditional template matching. The images are on the left show traditional template matching. As shown, the found centers on the left are off center. The images on the right show determining a center of the circle using the techniques described herein (e.g., methods 300 and 500), which show that the refined adjusted centers are more accurate.

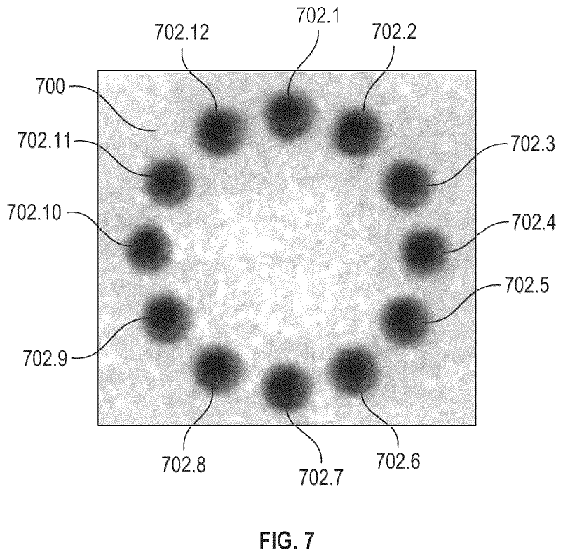

Fiducials can come in different forms and shapes. In some examples, a fiducial pattern can be provided, where the fiducial pattern includes a plurality of fiducial markings. FIG. 7 illustrates an example of a fiducial pattern 700. The fiducial pattern 700 includes twelve laser-drilled holes/vias 702.1-702.12 arranged in a circular pattern. The holes 702.1-702.12 can be about 30-60 microns in diameter. The holes 702.1-702.12 can be about 200 microns deep into a layer of dry film. The dry film, and other steps of the manufacturing process, can cause imperfections in the holes 702.1-702.12 causing them, in some instances, not to appear perfectly circular. These imperfections can impair conventional fiducial matching techniques, which are trained to find specified shapes. When the fiducial pattern includes variations causing imperfect shapes because of manufacturing variations, those conventional techniques can have difficulty identifying the fiducial pattern.

Next, improved techniques for identifying fiducial patterns are described. The techniques are robust such that they can identify fiducial patterns even when the fiducial patterns on the substrate include imperfect shapes or other imperfections.

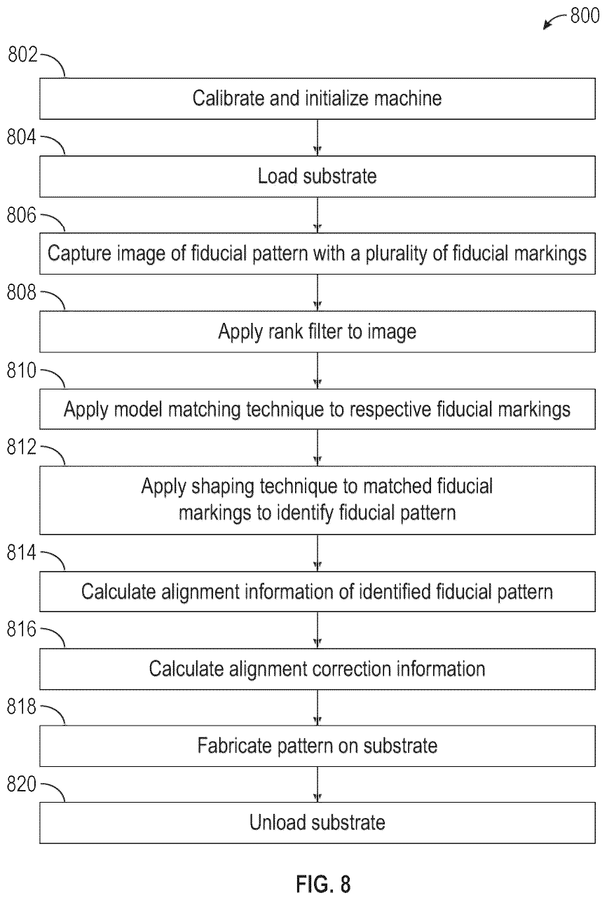

FIG. 8 illustrates a flow diagram for a method 800 for fiducial alignment. For example, the method 800 can be performed using the photolithography machine 100 for a substrate with the fiducial pattern 700, as described above.

At operation 802, the photolithography machine is calibrated and initialized. For example, instructions (e.g., recipe) for the fabrication may be retrieved and loaded. The instructions may include information such as fabrication layout, exposure time, size of each exposure region, number of exposure regions, layout of exposure regions, location of fiducial patterns, model/template of fiducial markings, etc. Instructions regarding different reticle patterns may be pre-stored in a memory associated with a controller of the photolithography machine, and the instructions for the particular reticle(s) may be retrieved based on the loaded reticles. Based on the instructions, the one or more microscope cameras in the alignment system may be moved in the x,y direction to match the fiducial pattern positions specified in the recipe.

At operation 804, the substrate is loaded onto the machine. For example, a load robot may place the substrate on the stage. The substrate may be clamped in place using edge clamps.

The alignment process using the fiducial pattern on the substrate may be initiated. In some examples, the substrate may include a plurality of exposure regions with each region including a fiducial pattern in a respective location in the region. In some examples, each exposure region may include a plurality of fiducial patterns (e.g., at four corners of the exposure region) to make exposure site correction, as described in further detail below.

At operation 806, a microscope camera captures an image of a respective fiducial pattern on the substrate. The fiducial pattern, for example, may be located at the corner of an exposure region. The fiducial pattern includes a plurality of fiducial markings, such as the fiducial pattern 700 described above with reference to FIG. 7.

At operation 808, a rank filter is applied to the image to reduce noise, such as speckled type noise. The rank filter, for example, can be a convolution or median filter with a configurable kernel size (e.g., 3×3, 5×5, 7×7). The rank filter can order or rank of pixel values within respective kernels. The pixels in the respective kernels can be sorted, and pixel with the median value is selected to replace the center pixel in the respective kernels.

At operation 810, a model matching technique is applied for matching the individual fiducial markings in the fiducial pattern (not the entire fiducial pattern). In the example of fiducial pattern 700, a model matching technique is used to match the individual holes 702.1-702.12 and not the entire fiducial pattern 700. The model matching technique can employ normalized cross correlation (or normalized grayscale correlation) instead of geometric type of edge detection, as used in some conventional systems.

For example, the normalized cross correlation technique may use a model or template of a fiducial marking (e.g., hole) from the instructions (see operation 802) to match each fiducial marking in the image. The model/template can be an image of a fiducial marking. The normalized cross correlation technique may measure the cross-correlation between pixel values in the captured image and the model at respective displacements while normalizing the correlation by a standard deviation of the two inputs. That is, the model or template can be slid over the captured image, and the normalized cross-correlation at each position can be calculated. The calculations can identify positions with high correlation scores to locate instances of the fiducial markings in the image. In some examples, the centers of the fiducial markings can be refined using the gradient maximizing techniques described above (see FIGS. 3-6 and their descriptions).

At operation 812, a shaping technique is applied to the matched fiducial markings to identify the fiducial pattern. The shaping technique can include a median circle fit technique for circular fiducial patterns, such as fiducial pattern 700. In some examples, the median circle fit technique can include determining a standard deviation of radii of the pattern and removing one or more outlier values based on the standard deviation. In some examples, the shaping technique can include performing linear regression on the data points associated with the fiducial markings and using a least square fit operation.

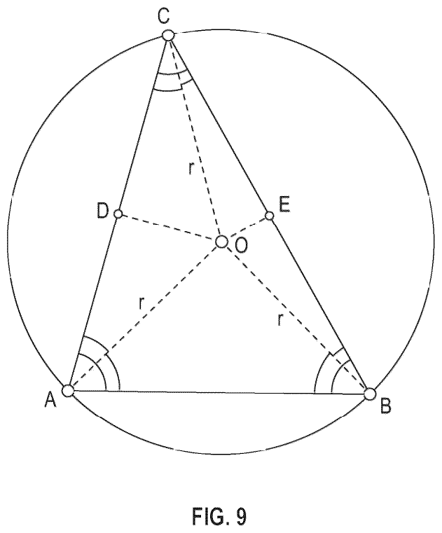

The median circle fit technique can find the best-fitting circle to a set of data points, which, in this case, would be the center of the individual fiducial markings. The respective centers of the individual fiducial markings can represent the data points (x, y). The technique can randomly select a subset of three points from the data set to form a circle hypothesis. Any three non-collinear points can define a unique circle. The technique can then calculate the parameters of the circle based on the selected three points. This can involve finding the center and radius (r) of the circle using geometric calculations. FIG. 9 illustrates an example of a median circle fit technique being applied to three data points. Here, points A, B, C are selected. Points D and E are calculated, which are used to find the center (O) and radius (r) of the circle.

For each data point, the technique can calculate the radial distance (residual) between the point and the estimated circle. The residual is the absolute difference between the actual distance and the radius of the circle. The residuals can be sorted to determine a median value. The technique is iterative in that the circle parameters may be refined by adjusting the hypothesis based on the median residual. This may involve re-estimating the circle parameters or selecting a new set of three points. The iterative process may be repeated for a set number of iterations.

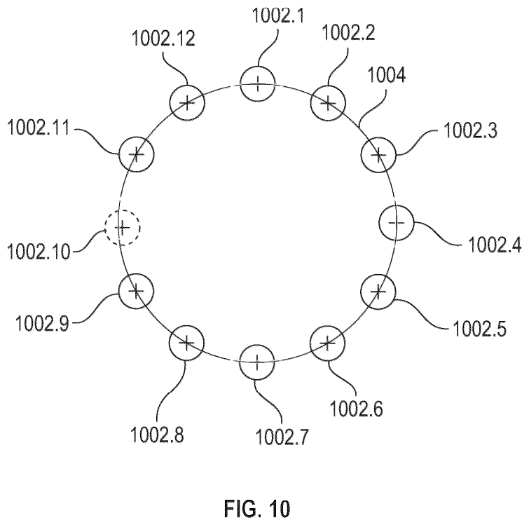

The median circle fit technique is particularly useful for identifying outlier values. FIG. 10 illustrates an example of a median circle fit technique being applied to a fiducial pattern, e.g., fiducial pattern 700 of FIG. 7. As shown, in FIG. 10, the fiducial pattern may include a plurality of fiducial markings 1002.1-1002.12. The fiducial markings 1002.1-1002.12 may be identified and their respective centers may be located using the techniques described herein. A median circle fit technique, as described above, is applied to determine a circle 1004 with radius r to fit the fiducial markings 1002.1-1002.12. The median circle fit technique identifies fiducial marking 1002.10 as an outlier value and removes the outlier value when fitting the circle 1004.

Returning to the discussion of method 800 in FIG. 8, at operation 814, alignment information for the exposure region may be calculated based on the identified fiducial pattern and its location in the image and specified location in the recipe.

At operation 816, alignment correction information may be calculated and stored for the exposure region. The alignment correction information may be related to the stage position and projection system settings for each exposure region, as described above. For example, a regression algorithm may be used to determine alignment correction information.

Next, the exposure process may be initiated. At operation 818, one or more patterns may be fabricated using the alignment correction information for the respective exposure regions. For example, the stage is moved so that the exposure region is provided below the projection system, and alignment correction is performed for the respective exposure region based on the alignment correction information for that exposure region. The projection system may then project an image on its reticle to fabricate the pattern on the image on the exposure region of the substrate. The exposure process then continues to the other exposure regions if needed.

After all exposure regions are fabricated, the stage is moved to an unload position and substrate is released and unloaded at operation 820. For example, the load robot may remove the substrate from the stage. Another substrate may be loaded on to the machine and the method may repeat (e.g., perform alignment and exposure process).

The fiducial patterns can also be analyzed to provide feedback to the manufacturing process so that, for example, the manufacturing process can be modified accordingly. For example, an inspection system can capture images of fiducial patterns on substrates and compare the fiducial patterns to templates, such as CAD designs, to determine variance values. The variance information can then be used to track the manufacturing process and identify possible issues. For example, the variance information can be transmitted to other servers and to semiconductor manufacturing equipment (such as a laser drilling machine) where such variance information can be used to modify the operations. In some examples, the inspection system can send the variance information to a stepper in a production line. The stepper uses the information received to calculate the stage and lens adjustments required to bring overlay back to a nominal position for better fiducial pattern processing. In another use case, a variance analysis algorithm computes a goodness of fit (GOF %) to the ideal fiducial pattern (100%). By correlating the GOF % vs. product overlay performance, the user can specify a GOF % threshold to stop processing (Stepper or Laser Drill tools) should the GOF % drop below the specified threshold value. This prevents scrap and low yielding products. Furthermore, each panel has multiple alignment fiducials, typically 4 per zone, 4 zones, for a total of 16 fiducials per panel. The variance algorithm could also be used to control the stepper's alignment fiducial selection, using fiducials with the highest GOF % and rejecting those that fall below a user defined threshold, as well as stipulating a minimum number of “valid” fiducials, e.g., 2 of 4 required before exposure of the patterns can commence.

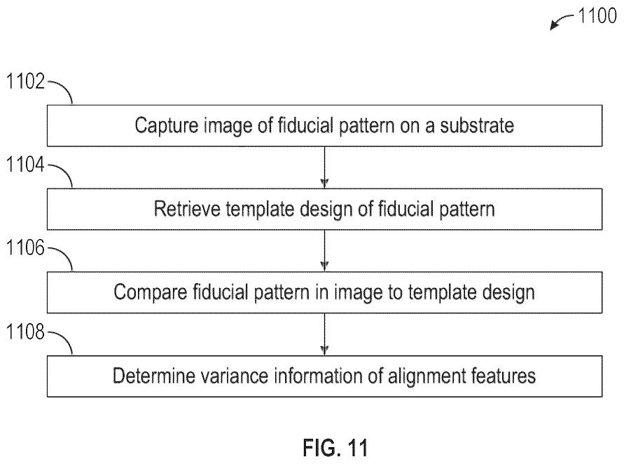

FIG. 11 is a flow diagram for a method 1100 for generating fiducial variance information. At operation 1102, an image of a respective fiducial pattern on the substrate is captured. The fiducial pattern, for example, may be located at the corner of an exposure region. The fiducial pattern can include a plurality of fiducial markings, such as the fiducial pattern 700 described above with reference to FIG. 7. For example, an inspection system can capture the image of the fiducial pattern.

At operation 1104, a template design of the fiducial pattern is retrieved. For example, the template design is a CAD design of the fiducial pattern.

At operation 1106, the fiducial pattern in the captured image is compared to the template design.

At operation 1108, variance information of the alignment features are determined based on the comparing the fiducial pattern in the captured image and the template design. For example, drift in variance from the nominal position of the fiducial pattern can be calculated.

In the example of a fiducial pattern including fiducial markings (e.g., fiducial pattern 700), variance information can be generated for respective fiducial markings as well as the entire fiducial pattern. For example, key metrics, such as visualization of X, Y position, Critical Dimension (CD) variation, hole roundness and correlation coefficient to the template design of the fiducial marking, can be generated. In addition, key metrics for the fiducial, such as visualization of X, Y position, CD variation, hole roundness and correlation coefficient to the template design of the fiducial pattern, can be generated.

The variance information of a plurality of substrates can be collected and combined. The large data set can be used to determine manufacturing issues resulting in the variance drift. For example, the variance information can be transmitted to other servers and to semiconductor manufacturing equipment (such as a laser drilling machine) where such variance information can be used to modify the operations. In some examples, the inspection system can send the variance information to a stepper in a production line. The stepper uses the information received to calculate the stage and lens adjustments required to bring overlay back to a nominal position for better fiducial pattern processing.

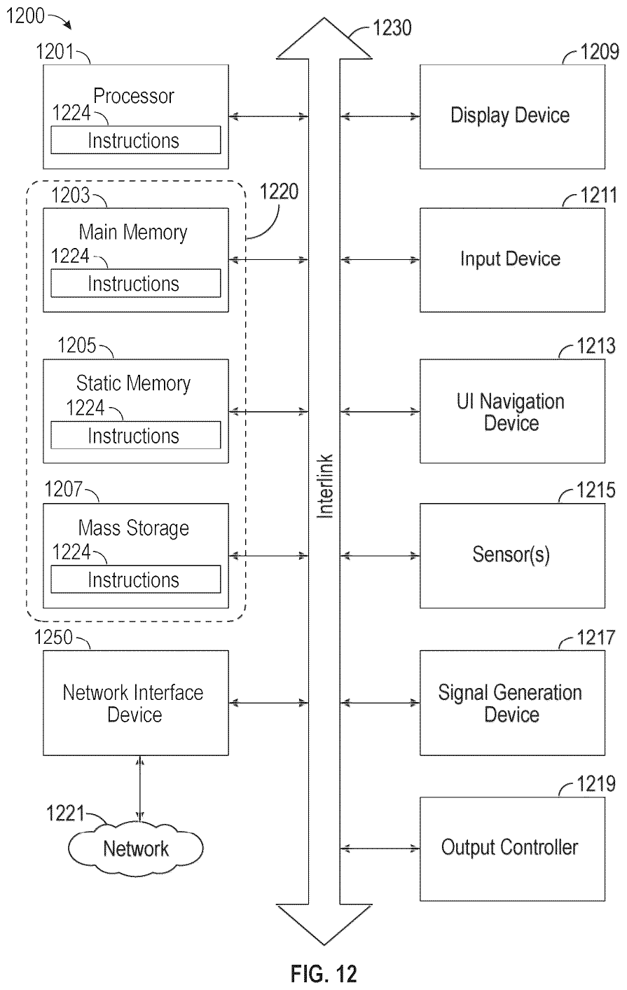

The techniques shown and described in this document can be performed using a portion or an entirety of photolithographic machine as shown in FIGS. 1-2 or an inspection system or otherwise using a machine 1200 as discussed below in relation to FIG. 12. FIG. 12 illustrates a block diagram of an example comprising a machine 1200 upon which any one or more of the techniques (e.g., methodologies) discussed herein may be performed. In various examples, the machine 1200 may operate as a standalone device or may be connected (e.g., networked) to other machines.

In a networked deployment, the machine 1200 may operate in the capacity of a server machine, a client machine, or both in server-client network environments. In an example, the machine 1200 may act as a peer machine in peer-to-peer (P2P) (or other distributed) network environment. The machine 1200 may be a personal computer (PC), a tablet device, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware comprising the circuitry may include variably connected physical components (e.g., execution units, transistors, simple circuits, etc.) including a computer-readable medium physically modified (e.g., magnetically, electrically, such as via a change in physical state or transformation of another physical characteristic, etc.) to encode instructions of the specific operation. In connecting the physical components, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 1200 (e.g., computer system) may include a hardware-based processor 1201 (e.g., a central processing unit (CPU), a graphics processing unit (GPU), a hardware processor core, or any combination thereof), a main memory 1203 and a static memory 1205, some or all of which may communicate with each other via an interlink 1230 (e.g., a bus). The machine 1200 may further include a display device 1209, an input device 1211 (e.g., an alphanumeric keyboard), and a user interface (UI) navigation device 1213 (e.g., a mouse). In an example, the display device 1209, the input device 1211, and the UI navigation device 1213 may comprise at least portions of a touch screen display. The machine 1200 may additionally include a storage device 1220 (e.g., a drive unit), a signal generation device 1217 (e.g., a speaker), a network interface device 1250, and one or more sensors 1215, such as a global positioning system (GPS) sensor, compass, accelerometer, or other sensor. The machine 1200 may include an output controller 1219, such as a serial controller or interface (e.g., a universal serial bus (USB)), a parallel controller or interface, or other wired or wireless (e.g., infrared (IR) controllers or interfaces, near field communication (NFC), etc., coupled to communicate or control one or more peripheral devices (e.g., a printer, a card reader, etc.).

The storage device 1220 may include a machine readable medium on which is stored one or more sets of data structures or instructions 1224 (e.g., software or firmware) embodying or utilized by any one or more of the techniques or functions described herein. The instructions 1224 may also reside, completely or at least partially, within a main memory 1203, within a static memory 1205, within a mass storage device 1207, or within the hardware-based processor 1201 during execution thereof by the machine 1200. In an example, one or any combination of the hardware-based processor 1201, the main memory 1203, the static memory 1205, or the storage device 1220 may constitute machine readable media.

While the machine readable medium is considered as a single medium, the term “machine readable medium” may include a single medium or multiple media (e.g., a centralized or distributed database, and/or associated caches and servers) configured to store the one or more instructions 1224.

The term “machine readable medium” may include any medium that is capable of storing, encoding, or carrying instructions for execution by the machine 1200 and that cause the machine 1200 to perform any one or more of the techniques of the present disclosure, or that is capable of storing, encoding or carrying data structures used by or associated with such instructions. Non-limiting machine-readable medium examples may include solid-state memories, and optical and magnetic media. Accordingly, machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic or other phase-change or state-change memory circuits; magnetic disks, such as internal hard disks and removable disks; magneto-optical disks; and CD-ROM and DVD-ROM disks.

The instructions 1224 may further be transmitted or received over a communications network 1221 using a transmission medium via the network interface device 1250 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., the Institute of Electrical and Electronics Engineers (IEEE) 702.22 family of standards known as Wi-Fi®, the IEEE 702.26 family of standards known as WiMax®), the IEEE 702.27.4 family of standards, peer-to-peer (P2P) networks, among others. In an example, the network interface device 1250 may include one or more physical jacks (e.g., Ethernet, coaxial, or phone jacks) or one or more antennas to connect to the communications network 1221. In an example, the network interface device 1250 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 1200, and includes digital or analog communications signals or other intangible medium to facilitate communication of such software.

### Various Notes

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in an aspect are still deemed to fall within the scope of that aspect. Moreover, in the following aspects, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following aspects are hereby incorporated into the Detailed Description as examples or implementations, with each aspect standing on its own as a separate implementation, and it is contemplated that such implementations can be combined with each other in various combinations or permutations.

Described implementations of the subject matter can include one or more features, alone or in combination as illustrated below by way of example.

Example 1. A method to align a substrate for lithography, the method comprising: receiving an image of the substrate including a fiducial pattern with a plurality of fiducial markings; applying a model matching technique to match respective fiducial markings of the plurality of fiducial markings based on a model fiducial marking; applying a shaping technique to the matched fiducial markings to identify the fiducial pattern; and transmitting instructions for aligning the substrate based on a location of the identified fiducial pattern.

Example 2. The method of example 1, wherein applying the model matching technique includes: measuring a cross-correlation between pixel values in the image and the model fiducial marking at respective displacements; and normalizing the cross-correlation by a standard deviation of the pixel values.

Example 3. The method of any of examples 1-2, wherein the shaping technique includes a median circle fit algorithm.

Example 4. The method of any of examples 1-3, wherein the median circle fit algorithm includes: determining a plurality of radius values of the fiducial pattern based on at least one subset of fiducial markings; determining a standard deviation of the plurality of radius values; and removing at least one outlier value of the matched fiducial markings based on the standard deviation of the plurality of radius values.

Example 5. The method of any of examples 1-4, further comprising: applying a rank filter to the image.

Example 6. The method of any of examples 1-5, further comprising: aligning the substrate based on the instructions, wherein the instructions include alignment correction information; and projecting at least one image on the substrate based on the alignment correction information.

Example 7. The method of any of examples 1-6, wherein the fiducial pattern with the plurality of fiducial markings includes a plurality of laser drilled holes arranged in a circular pattern.

Example 8. The method of any of examples 1-7, wherein the model fiducial marking is a template, and wherein applying the model matching technique includes: matching a respective fiducial marking with the template; determining an initial center position of the respective fiducial marking based on the matching; refining the initial center position of the respective fiducial marking based on gradient values to determine a refined center position.

Example 9. The method of any of examples 1-8, wherein refining the initial center position includes: applying a median filter to the image; determining gradient values for pixels in the image; applying a correlation technique for matching gradient values with a nominal shape of the fiducial marking; and determining the refined center position based on the correlation technique.

Example 10. The method of any of examples 1-9, further comprising: retrieving a template design of the fiducial pattern; comparing fiducial pattern in image to template design; and determining variance information of alignment features of fiducial pattern based on comparing fiducial pattern in image to template design.

Example 11. The method of any of examples 1-10, further comprising: generating a key metric based on the variance information.

Example 12. The method of any of examples 1-11, wherein the key metric is a visualization of X, Y position, CD variation, hole roundness and correlation coefficient to the template design of the fiducial pattern.

Example 13. A method to determine a refined center position of a fiducial marking, the method comprising: receiving an image of a substrate including the fiducial marking; matching the fiducial marking in the image with a template of the fiducial marking; determining an initial center position of the fiducial marking based on the matching; and determining the refined center position of the fiducial marking based on maximizing a sum or mean of gradient magnitude values within a shape of the fiducial marking.

Example 14. The method of example 13, wherein the fiducial marking is a laser-drilled hole.

Example 15. The method of any of examples 13-14, wherein determining the refined center position of the fiducial marking includes: generating gradient values for a set of pixels in the image; applying a correlation technique for matching the gradient values to a nominal shape of the fiducial marking; determining the refined center based on results of the correlation technique.

Example 16. The method of any of examples 13-15, wherein the gradient values are generated using a Sobel filter.

Example 17. The method of any of examples 13-16, further comprising: applying a median filter to the image.

Example 18. A method for generating fiducial variance information for aligning a substrate, the method comprising: receiving an image of the substrate including a fiducial pattern with a plurality of fiducial markings; retrieving a template design of the fiducial pattern; comparing the fiducial pattern the image to the template design; and determining variance information of alignment features of the fiducial pattern based on the comparing.

Example 19. The method of example 18, further comprising: collecting variance information for a plurality of substrates; transmitting instructions to a stepper machine to adjust manufacturing of the fiducial pattern based on the variance information for the plurality of substrates.

Example 20. The method of any of examples 18-19, further comprising: generating a key metric based on the variance information.

Example 21. The method of any of examples 18-20, wherein the key metric is a visualization of X, Y position, CD variation, hole roundness and correlation coefficient to the template design of the fiducial pattern.

Example 22. A system comprising: at least one hardware processor; and at least one memory storing instructions that, when executed by the at least one hardware processor, cause the at least one hardware processor to perform operations implementing any one of example methods 1 to 21.

Example 23. A machine-readable medium embodying instructions that, when executed by a machine, cause the machine to perform operations implementing any one of example methods 1 to 21.

1. A method to align a substrate for lithography, the method comprising:
receiving an image of the substrate including a fiducial pattern with a plurality of fiducial markings;
applying a model matching technique to match respective fiducial markings of the plurality of fiducial markings based on a model fiducial marking;
applying a shaping technique to the matched fiducial markings to identify the fiducial pattern; and
transmitting instructions for aligning the substrate based on a location of the identified fiducial pattern.

2. The method of claim 1, wherein applying the model matching technique includes:
measuring a cross-correlation between pixel values in the image and the model fiducial marking at respective displacements; and
normalizing the cross-correlation by a standard deviation of the pixel values.

3. The method of claim 1, wherein the shaping technique includes a median circle fit algorithm.

4. The method of claim 3, wherein the median circle fit algorithm includes:
determining a plurality of radius values of the fiducial pattern based on at least one subset of fiducial markings;
determining a standard deviation of the plurality of radius values; and
removing at least one outlier value of the matched fiducial markings based on the standard deviation of the plurality of radius values.

5. The method of claim 1, further comprising:
aligning the substrate based on the instructions, wherein the instructions include alignment correction information; and
projecting at least one image on the substrate based on the alignment correction information.

6. The method of claim 1, wherein the fiducial pattern with the plurality of fiducial markings includes a plurality of laser drilled holes arranged in a circular pattern.

7. The method of claim 1, wherein the model fiducial marking is a template, and wherein applying the model matching technique includes:
matching a respective fiducial marking with the template;
determining an initial center position of the respective fiducial marking based on the matching;
refining the initial center position of the respective fiducial marking based on gradient values to determine a refined center position.

8. The method of claim 7, wherein refining the initial center position includes:
applying a median filter to the image;
determining gradient values for pixels in the image;
applying a correlation technique for matching gradient values with a nominal shape of the fiducial marking; and
determining the refined center position based on the correlation technique.

9. The method of claim 1, further comprising:
retrieving a template design of the fiducial pattern;
comparing fiducial pattern in image to template design;
determining variance information of alignment features of fiducial pattern based on comparing fiducial pattern in image to template design;
generating a key metric based on the variance information, wherein the key metric is a visualization of X, Y position, CD variation, hole roundness and correlation coefficient to the template design of the fiducial pattern.

10. A system comprising:
at least one hardware processor; and
at least one memory storing instructions that, when executed by the at least one hardware processor, cause the at least one hardware processor to perform operations comprising:
receiving an image of a substrate including a fiducial pattern with a plurality of fiducial markings;
applying a model matching technique to match respective fiducial markings of the plurality of fiducial markings based on a model fiducial marking;
applying a shaping technique to the matched fiducial markings to identify the fiducial pattern; and
transmitting instructions for aligning the substrate based on a location of the identified fiducial pattern.

11. The system of claim 10, wherein applying the model matching technique includes:
measuring a cross-correlation between pixel values in the image and the model fiducial marking at respective displacements; and
normalizing the cross-correlation by a standard deviation of the pixel values.

12. The system of claim 10, wherein the shaping technique includes a median circle fit algorithm.

13. The system of claim 12, wherein the median circle fit algorithm includes:
determining a plurality of radius values of the fiducial pattern based on at least one subset of fiducial markings;
determining a standard deviation of the plurality of radius values; and
removing at least one outlier value of the matched fiducial markings based on the standard deviation of the plurality of radius values.

14. The system of claim 10, the operations further comprising:
aligning the substrate based on the instructions, wherein the instructions include alignment correction information; and
projecting at least one image on the substrate based on the alignment correction information.

15. The system of claim 10, wherein the fiducial pattern with the plurality of fiducial markings includes a plurality of laser drilled holes arranged in a circular pattern.

16. The system of claim 10, wherein the model fiducial marking is a template, and wherein applying the model matching technique includes:
matching a respective fiducial marking with the template;
determining an initial center position of the respective fiducial marking based on the matching;
refining the initial center position of the respective fiducial marking based on gradient values to determine a refined center position.

17. The system of claim 16, wherein refining the initial center position includes:
applying a median filter to the image;
determining gradient values for pixels in the image;
applying a correlation technique for matching gradient values with a nominal shape of the fiducial marking; and
determining the refined center position based on the correlation technique.

18. The system of claim 10, the operations further comprising:
retrieving a template design of the fiducial pattern;
comparing fiducial pattern in image to template design;
determining variance information of alignment features of fiducial pattern based on comparing fiducial pattern in image to template design;
generating a key metric based on the variance information, wherein the key metric is a visualization of X, Y position, CD variation, hole roundness and correlation coefficient to the template design of the fiducial pattern.

19. A machine-readable medium embodying instructions that, when executed by a machine, cause the machine to perform operations comprising:
receiving an image of a substrate including a fiducial pattern with a plurality of fiducial markings;
applying a model matching technique to match respective fiducial markings of the plurality of fiducial markings based on a model fiducial marking;
applying a shaping technique to the matched fiducial markings to identify the fiducial pattern; and
transmitting instructions for aligning the substrate based on a location of the identified fiducial pattern.

20. The machine-readable medium of claim 19, wherein applying the model matching technique includes:
measuring a cross-correlation between pixel values in the image and the model fiducial marking at respective displacements; and
normalizing the cross-correlation by a standard deviation of the pixel values.

21. The machine-readable medium of claim 19, wherein the shaping technique includes a median circle fit algorithm.

22. The machine-readable medium of claim 21, wherein the median circle fit algorithm includes:
determining a plurality of radius values of the fiducial pattern based on at least one subset of fiducial markings;
determining a standard deviation of the plurality of radius values; and
removing at least one outlier value of the matched fiducial markings based on the standard deviation of the plurality of radius values.

23. The machine-readable medium of claim 19, the operations further comprising:
aligning the substrate based on the instructions, wherein the instructions include alignment correction information; and
projecting at least one image on the substrate based on the alignment correction information.

24. The machine-readable medium of claim 19, wherein the fiducial pattern with the plurality of fiducial markings includes a plurality of laser drilled holes arranged in a circular pattern.

25. The machine-readable medium of claim 19, wherein the model fiducial marking is a template, and wherein applying the model matching technique includes:
matching a respective fiducial marking with the template;
determining an initial center position of the respective fiducial marking based on the matching;
refining the initial center position of the respective fiducial marking based on gradient values to determine a refined center position.

26. The machine-readable medium of claim 25, wherein refining the initial center position includes:
applying a median filter to the image;
determining gradient values for pixels in the image;
applying a correlation technique for matching gradient values with a nominal shape of the fiducial marking; and
determining the refined center position based on the correlation technique.

27. The machine-readable medium of claim 19, the operations further comprising:
retrieving a template design of the fiducial pattern;
comparing fiducial pattern in image to template design;
determining variance information of alignment features of fiducial pattern based on comparing fiducial pattern in image to template design; generating a key metric based on the variance information, wherein the key metric is a visualization of X, Y position, CD variation, hole roundness and correlation coefficient to the template design of the fiducial pattern.
